(19) United States
(12) Patent Application Publication
(10) Pub. No.: US 2010/0266246 A1
(43) Pub. Date: Oct. 21, 2010

(54) EMI SHIELDING AND/OR GROUNDING GASKETS

(75) Inventor: Philip van Haaster, Corona, CA (US)

Correspondence Address: HARNESS, DICKEY, & PIERCE, P.L.C, 7700 Bonhomme, Suite 400, ST. LOUIS, MO, 63105, US

(73) Assignee: LAIRD TECHNOLOGIES, INC., Chesterfield, MO (US)

(21) Appl. No.: 12/761,115

(22) Filed: Apr. 15, 2010

Related U.S. Application Data
(60) Provisional application No. 61/170,522, filed on Apr. 17, 2009.

(51) Int. Cl. G02B 6/36; H05K 9/00; B23P 11/00

(52) U.S. Cl. 385/94; 174/354; 29/428

(57) ABSTRACT

An electromagnetic interference (EMI) shielding and/or grounding gasket generally includes one or more sides and slots along the one or more sides. Finger elements are defined by the slots. The finger elements include contact portions for electrically contacting at least one electrically conductive surface adjacent to a mounting surface when the gasket is mounted thereto with its one or more sides disposed about and in electrical contact with the mounting surface. The gasket may thus be operable for establishing an electrically conductive pathway between the electrically-conductive surface and the mounting surface.

### CROSS-REFERENCE TO RELATED APPLICATION

This application claims the benefit of U.S. Provisional Application No. 61/170,522 filed Apr. 17, 2009. The entire disclosure of the above application is incorporated herein by reference.

### FIELD

The present disclosure generally relates to electromagnetic interference (EMI)/radio frequency interference (RFI) shielding and/or grounding gaskets.

### BACKGROUND

This section provides background information related to the present disclosure which is not necessarily prior art.

Selected electronic parts radiate electromagnetic waves, which can cause noise or unwanted signals to appear in electronic devices existing within a certain proximity of the radiating parts. Accordingly, it is not uncommon to provide shielding and/or grounding for electronic components that use circuitry that emits or is susceptible to electromagnetic radiation. These components may be shielded to reduce undesirable electromagnetic interference and/or susceptibility effects with the use of a conductive shield that reflects or dissipates electromagnetic charges and fields. Such shielding may be grounded to allow the offending electrical charges and fields to be dissipated without disrupting the operation of the electronic components enclosed within the shield.

As used herein, the term electromagnetic interference (EMI) should be considered to generally include and refer to both electromagnetic interference (EMI) and radio frequency interference (RFI) emissions. The term “electromagnetic” should be considered to generally include and refer to both electromagnetic and radio frequency from external sources and internal sources. Accordingly, the term shielding (as used herein) generally includes and refers to both EMI shielding and RFI shielding, for example, to prevent (or at least reduce) ingress and egress of EMI and RFI relative to a shielding device in which electronic equipment is disposed.

### SUMMARY

This section provides a general summary of the disclosure, and is not a comprehensive disclosure of its full scope or all of its features.

An exemplary embodiment of an electromagnetic interference (EMI) shielding and/or grounding gasket generally includes one or more sides and slots along the one or more sides. Finger elements are defined by the slots. The finger elements include contact portions for electrically contacting at least one electrically conductive surface adjacent to a mounting surface when the gasket is mounted thereto with its one or more sides disposed about and in electrical contact with the mounting surface. The gasket may thus be operable for establishing an electrically conductive pathway between the electrically-conductive surface and the mounting surface.

Also disclosed are exemplary methods relating to an electromagnetic interference (EMI) shielding and/or grounding gasket. The gasket may include one or more sides, slots along the one or more sides, and finger elements defined by the slots such that the finger elements include contact portions. In an example embodiment, a method may generally include positioning the gasket relative to the mounting surface such that the gasket's one or more sides are circumferentially disposed about and in electrical contact with the mounting surface.

An exemplary embodiment is also provided of a flexible clip-on EMI shielding and/or grounding gasket mountable circumferentially about a rectangular mounting surface of a optical transceiver module for providing EMI shielding and/or electrical grounding contact between the optical transceiver module and another electrically conductive surface. In this exemplary embodiment, the gasket generally includes four sides defining a rectangular opening complementary in shape to the rectangular mounting surface. Closed-ended slots are along the four sides. Resiliently flexible finger elements are defined by the slots. The finger elements include contact portions for electrically contacting an interior surface of a collar slidably installed over the gasket while installed on the mounting surface with each of the gasket's four sides circumferentially disposed about and in electrical contact with a corresponding one of the sides of the rectangular mounting surface.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective view of a flexible clip-on EMI shielding and/or grounding gasket according to an exemplary embodiment of the present disclosure;

FIG. 2 is a forward view of the gasket shown in FIG. 1;

FIG. 3 is an upper view of the gasket shown in FIG. 1;

FIG. 4 is a side view of the gasket shown in FIG. 1;

FIG. 5 is a cross-sectional view of the gasket taken along the plane 5-5 in FIG. 2;

FIG. 6 is a forward view of the gasket shown in FIG. 1 with exemplary dimensions in millimeters (inches are provided in brackets) provided for purposes of illustration only according to exemplary embodiments;

FIG. 7 is a cross-sectional view of the gasket taken along the plane 7-7 in FIG. 6, with exemplary dimensions in millimeters (inches are provided in brackets) provided for purposes of illustration only according to exemplary embodiments;

FIG. 8 is a perspective view illustrating the gasket shown in FIG. 1 mounted and installed circumferentially around a forward portion of a pluggable optical transceiver module in accordance with an exemplary embodiment;

FIG. 9 is a perspective view of the pluggable optical transceiver module shown in FIG. 8, and also illustrating a collar installed generally over the gasket, whereby the gasket relatively slides into the collar and makes contact with the collar's inside surface, such that the gasket establishes electrical grounding contact from the collar to the forward portion of the pluggable optical transceiver module;

FIG. 10 is a partial perspective view of the pluggable optical transceiver module and gasket shown in FIG. 8; and

FIG. 11 is a side elevation view of the pluggable optical transceiver module and gasket shown in FIG. 10 with the collar of FIG. 9 shown in broken lines.

Corresponding reference numerals indicate corresponding parts throughout the several views of the drawings.

### DETAILED DESCRIPTION

Example embodiments will now be described more fully with reference to the accompanying drawings.

According to various aspects, exemplary embodiments are provided of EMI shielding and/or grounding gaskets, which may be used with optical transceiver modules, among other devices, etc. Other aspects relate to methods of using and/or making EMI shielding and/or grounding gaskets.

By way of example, an exemplary gasket disclosed herein may be used with a “CFP module,” which is a fiber optic transceiver module that meets the MSA (Multi-Source Agreement) Specification. According to http://www.cfp-msa.org/, the CFP MSA defines a hot-pluggable optical transceiver form factor to enable 40 gigabits per second and 100 gigabits per second applications, such as interfaces for Ethernet, Telecommunication, and other applications.

In an exemplary embodiment, an electromagnetic interference (EMI) shielding and/or grounding gasket generally includes one or more sides and slots along the one or more sides. Finger elements are defined by the slots. The finger elements include contact portions for electrically contacting at least one electrically conductive surface adjacent to a mounting surface when the gasket is mounted thereto with its one or more sides disposed about and in electrical contact with the mounting surface. The gasket may thus be operable for establishing an electrically conductive pathway between the electrically-conductive surface and the mounting surface.

Also disclosed are exemplary methods relating to an electromagnetic interference (EMI) shielding and/or grounding gasket. The gasket may include one or more sides, slots along the one or more sides, and finger elements defined by the slots such that the finger elements include contact portions. In an example embodiment, a method may generally include positioning the gasket relative to the mounting surface such that the gasket's one or more sides are circumferentially disposed about and in electrical contact with the mounting surface.

An exemplary embodiment is also provided of a flexible clip-on EMI shielding and/or grounding gasket mountable circumferentially about a rectangular mounting surface of a optical transceiver module for providing EMI shielding and/or electrical grounding contact between the optical transceiver module and another electrically conductive surface. In this exemplary embodiment, the gasket generally includes four sides defining a rectangular opening complementary in shape to the rectangular mounting surface. Closed-ended slots are along the four sides. Resiliently flexible finger elements are defined by the slots. The finger elements include contact portions for electrically contacting an interior surface of a collar slidably installed over the gasket while installed on the mounting surface with each of the gasket's four sides circumferentially disposed about and in electrical contact with a corresponding one of the sides of the rectangular mounting surface.

An exemplary embodiment is also provided of a flexible clip-on EMI shielding and/or grounding gasket mountable circumferentially about a rectangular mounting surface of a optical transceiver module for providing EMI shielding and/or electrical grounding contact between the optical transceiver module and another electrically conductive surface. In this exemplary embodiment, the gasket generally includes four sides defining a rectangular opening complementary in shape to the rectangular mounting surface. Closed-ended slots are along the four sides. Resiliently flexible finger elements are defined by the slots. The finger elements include contact portions for electrically contacting an interior surface of a collar slidably installed over the gasket while installed on the mounting surface with each of the gasket's four sides circumferentially disposed about and in electrical contact with a corresponding one of the sides of the rectangular mounting surface.

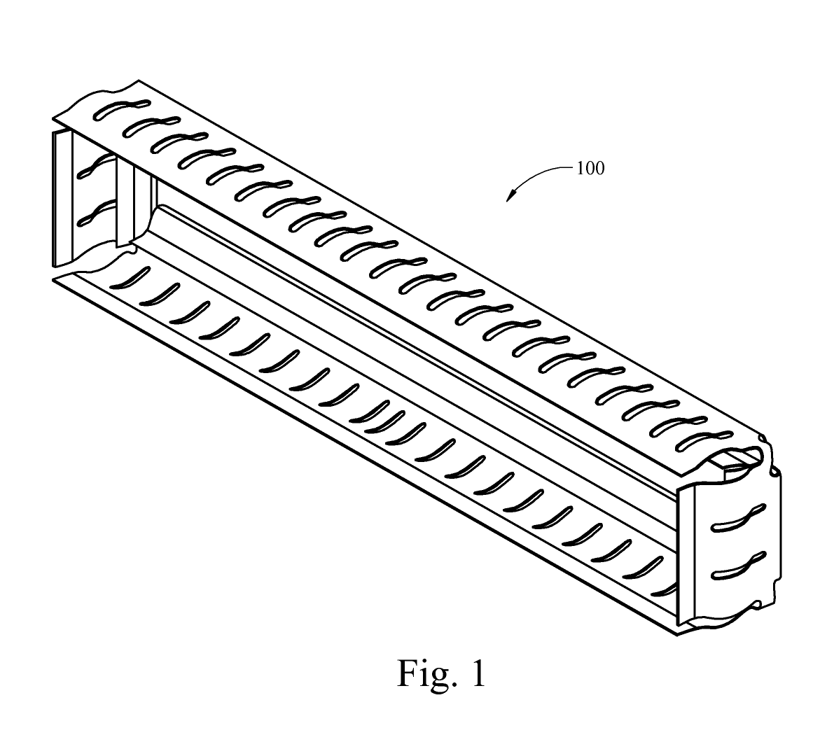

FIGS. 1 through 5 illustrate an exemplary flexible clip-on EMI shielding and/or grounding gasket or grounding strip 100 embodying aspects of the present disclosure. Hereinafter, flexible clip-on EMI shielding and/or grounding gasket or strip 100 will be referred to as the gasket 100 for convenience.

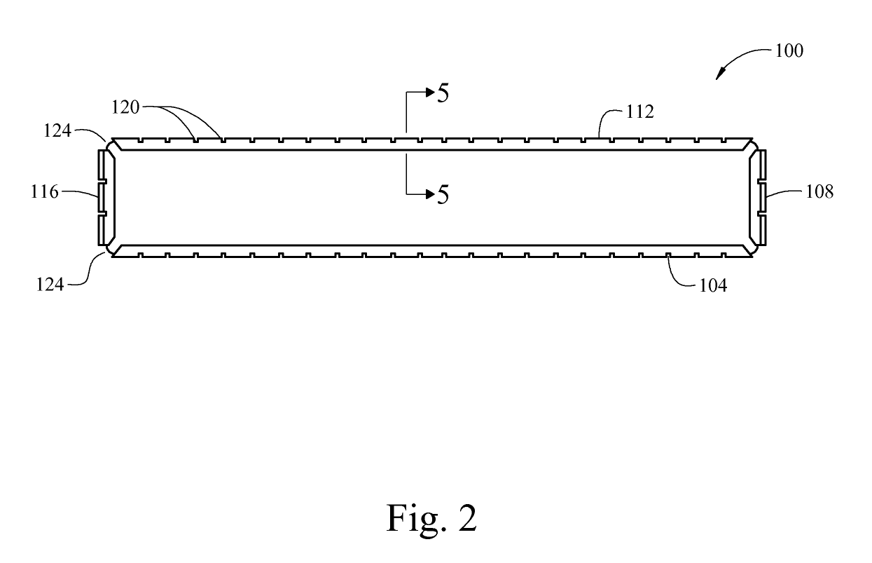

As shown in FIG. 2, the gasket 100 includes a generally rectangular configuration with four sides 104, 108, 112, 116. The four sides 104, 108, 112, 116 define a generally rectangular perimeter or opening. The opening may have a shape complementary to a shape of a mounting surface such that the gasket 100 is mountable with the gasket's sides 104, 108, 112, 116 circumferentially disposed about and in electrical contact with a corresponding side of the mounting surface. As shown in FIGS. 1, 3, and 4, the sides 104, 108, 112, 116 of the gasket 100 are curved or bowed slightly outward.

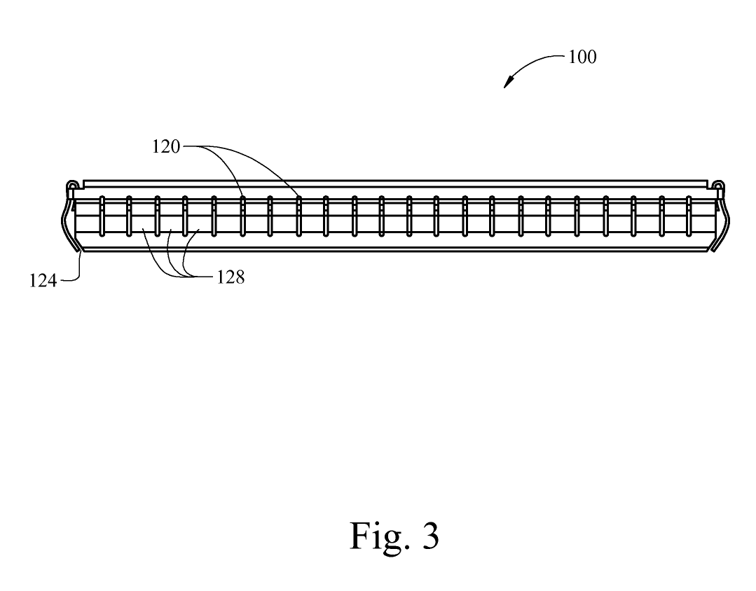

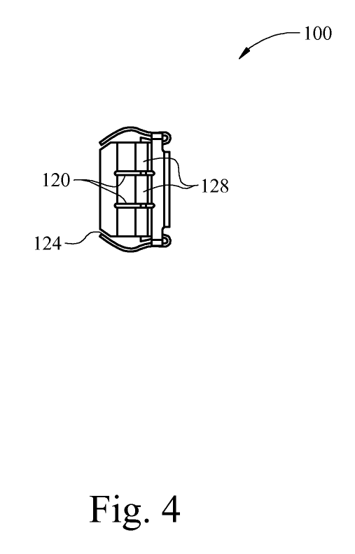

The gasket 100 also includes slots or slits 120 along each side 104, 108, 112, 116. As shown in FIGS. 3 and 4, both ends of each slot 120 are closed, such that the slots 120 do not extend completely through any edges of the gasket 100. In other embodiments, however, one or more of the slots 120 may include one end that is open and extends completely through a lateral edge of the gasket 100. Alternative embodiments may, for example, include less or more slots and finger elements than what is shown in the figures. Further embodiments may include other slot arrangements and orientations besides slots as shown in the figures.

At each corner of the gasket 100, there is an opening or slot 124. Each corner slot 124 has one end portion that is open and another end portion that is closed. The corner slots 124 may be configured to increase the flexibility of the gasket 100 by allowing or permitting each side 104, 108, 112, 116 of the gasket 100 to move relative to its adjacent sides. For example, the corner slots 124 between the gasket's side 108 and sides 104, 112 may allow at least some outward movement of the side 108 relative to the adjacent sides 104, 112. In turn, this may facilitate and make it easier to mount the gasket 100 circumferentially about a mounting surface.

The slots 120 define finger elements 128 therebetween. The slots 108 increase the flexibility of the finger elements 128. The slots 108 may also allow some relatively independent movement (e.g., inwardly flexed or compressed, etc.) of the contact elements 140 of the gasket 100 on opposite sides of a slit 108. In addition, the contact elements 140 on one side of the gasket 100 may be able to move relatively independently of the contact elements 140 on another side of the gasket 100. For example, the finger elements 128 along one side of the gasket 100 may be configured such that they are independently operable from the finger elements 128 along another side of the gasket 100.

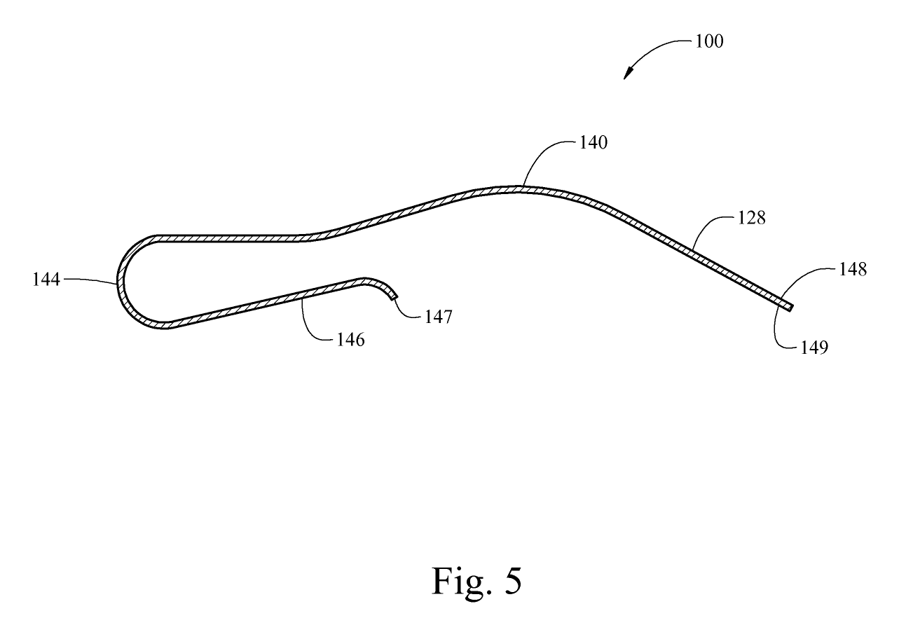

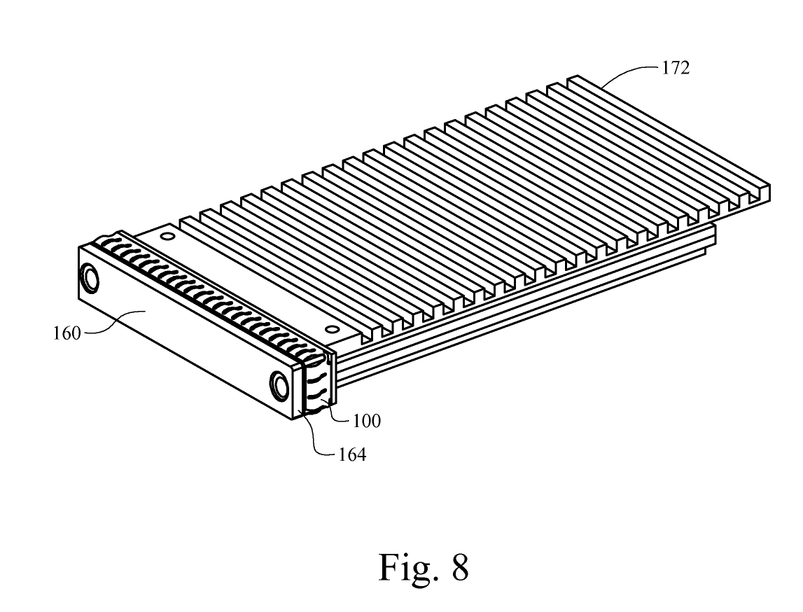

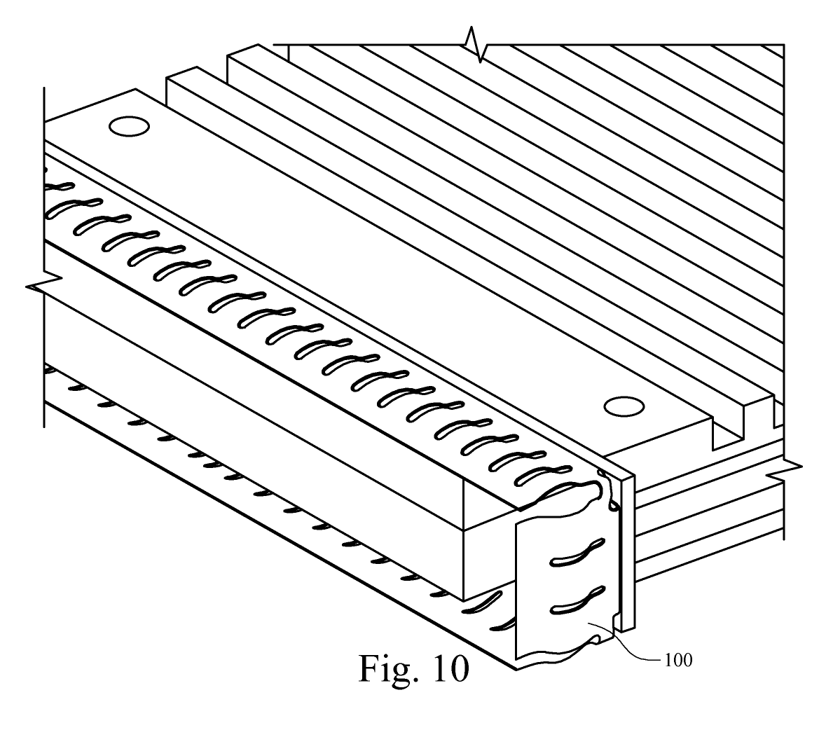

FIG. 5 illustrates the exemplary profile for the gasket 100. As shown, the gasket 100 includes contact portions 140 defined by the finger elements 128. The finger elements 128 curve generally downward from the contact portion 140 to eventually define a u-shaped hook portion 144 having an lower portion 146 and free end 147. The finger elements 128 also curve generally downward in the other direction to form a leading edge, end, or tip 148 having a lower surface 149. The leading edges 148 of the finger elements 128 are preferably configured to be below the mounting surface (e.g., forward portion 164 of an optical transceiver module 160 (FIGS. 8 through 11), etc.) when the finger elements 128 are in a free, uncompressed state. Upon installation, the finger elements 128 will be in a restrained or compressed condition such that a downward load is applied onto the mounting surface. This spring load (or pre-load) will discourage or inhibit any lifting of the finger during module extraction. In an exemplary embodiment, the gasket 100 is configured to have an insertion load of 36 Newtons and a contact load of 320 grams, thus surpassing the 200 gram contact load typically needed for making good electrical contact between two metal surfaces or other electrically-conductive surfaces.

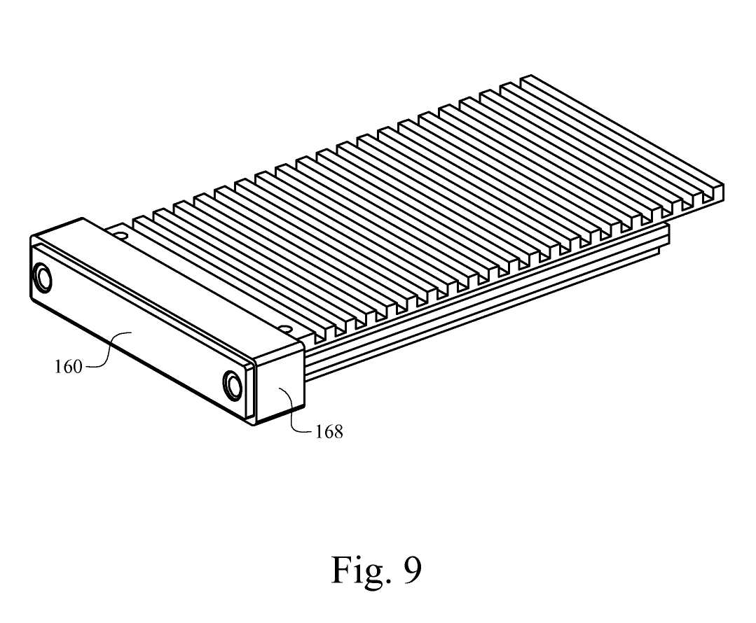

The gasket 100 may be used as a shielding and/or grounding strip by contacting another surface that would bear against the contact portion 140 defined by the finger elements 128, for example, with a force having a component perpendicular to the corresponding side 104, 108, 112, 116 of the gasket 100. In use, the finger elements 128 and contact portion 140 can be borne against by another surface (e.g., inside surface of the collar 168 shown in FIG. 9, etc.) causing the finger elements 128 to flex along their length, thus bringing the contact portion 140 closer to a mounting surface. In some embodiments, the finger elements 128 are configured to be compressed or flexed inwardly toward the mounting surface when another surface bears against the contact portions 140 of the finger elements 128 and applies sufficient pressure against a force resiliently biasing the contact portions 140 in a generally outward direction from the mounting surface.

When the loading surface is removed from being in contact with gasket 100, the resilient nature of the material out of which the gasket 100 and/or finger elements 128 are preferably constructed allows the finger elements 128 to return to their unloaded positions. The material from which the gasket 100 is constructed may preferably be selected so that during use of the gasket 100 as a shielding and/or grounding strip, the yield point of the material is not reached and no plastic deformation of the material occurs.

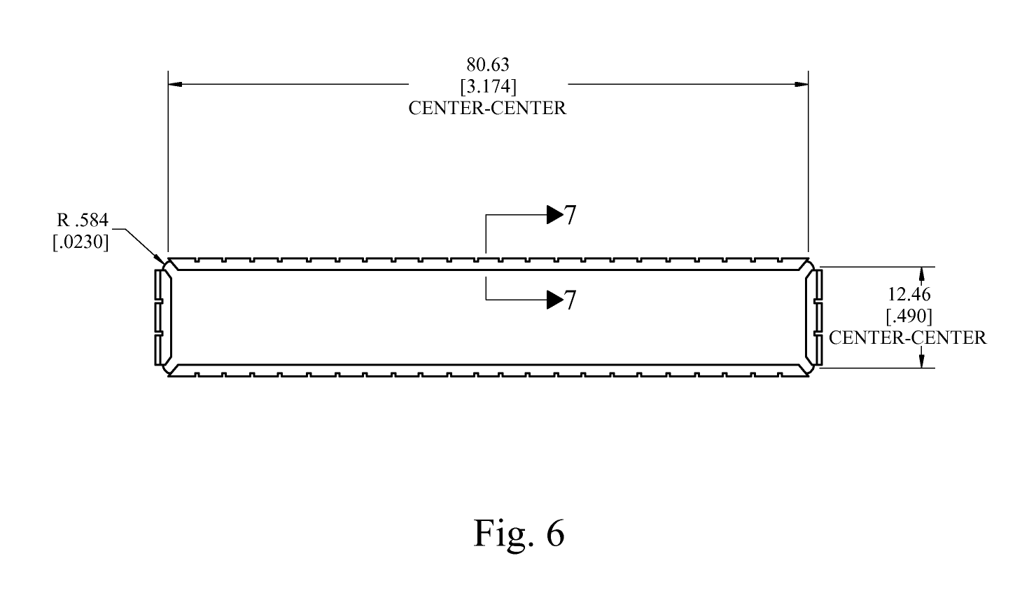

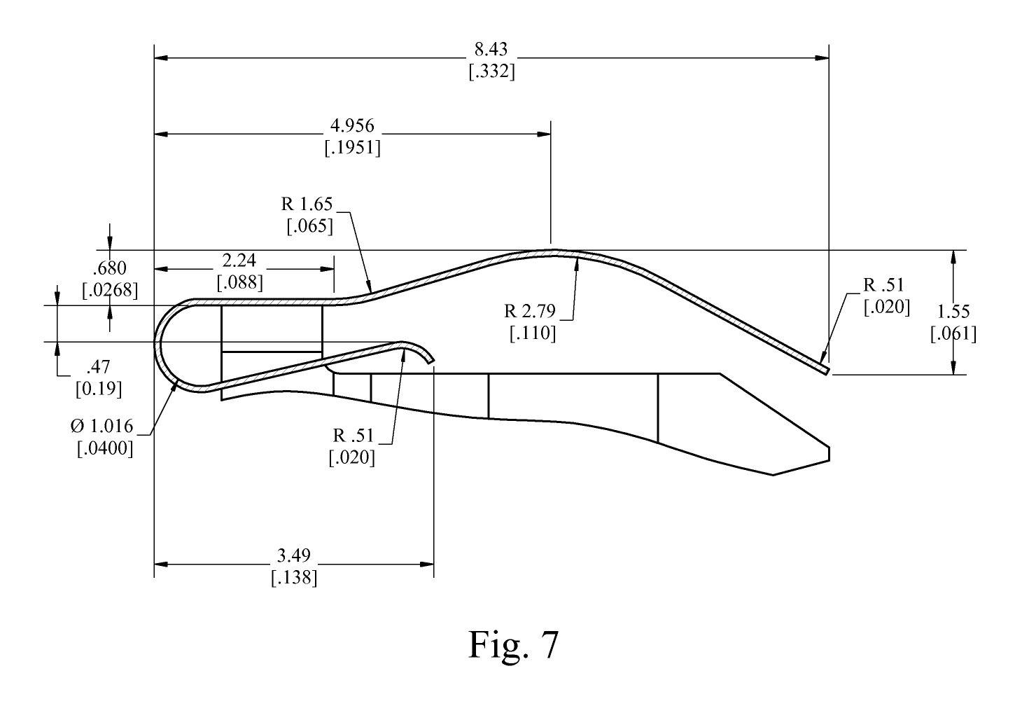

FIGS. 6 and 7 illustrate exemplary dimensions in millimeters (inches are set forth in brackets) that may be used for the gasket 100 shown in FIGS. 1 through 5 for purposes of illustration only and not for purposes of limitation. These dimensions (as are all dimensions set forth herein) are for purposes of illustration only as the specific dimensions for a particular application can depend, for example, upon the length of the gasket, desired shielding effectiveness, material properties of the gasket, and particular installation (e.g., configuration of the mounting surface on which the gasket will be positioned, amount of curvature or bending needed for installing the gasket, etc.). In addition, the dimensions may vary as a function of location such that the shielding strip is thicker in one region than another to accommodate gaps of different thickness in the enclosure and connector locations. Accordingly, the dimensions of the shielding strip may be varied accordingly in order to achieve the desired contact.

In various embodiments, the gasket 100 may be integrally or monolithically formed as a single component. For example, the gasket 100 may be formed by stamping slots or slits 120 into a piece of material. After stamping the piece of material, the material may be folded, bent, or otherwise formed to form the profile of the finger elements 128 (FIG. 5), sides 104, 108, 112, 116, and generally rectangular configuration (FIG. 2) of the gasket 100. Even though the gasket 100 may be formed integrally in this example, such is not required for all embodiments. Alternative configurations (e.g., shapes, sizes, etc.), materials, and manufacturing methods (e.g., drawing, etc.) may be used for making the gasket 100.

A wide range of materials may be used for a gasket (e.g., 100, etc.) disclosed herein, including resiliently flexible, electrically conductive, soft and/or heat treatable materials. In various embodiments, a gasket is formed from resiliently flexible material that is elastic in nature with a modulus of elasticity sufficient so that the gasket and/or the finger elements can be displaced by a force from an unloaded position to a loaded position, and then return to the unloaded position upon the removal of this force without exceeding the yield point of the material. Additionally, or alternatively, the gasket in some embodiments is formed from an electrically-conductive material capable of conducting electricity therethrough with impedance sufficiently low enough to be an effective EMI/RFI shield.

By way of further example, some embodiments include a gasket formed from beryllium copper alloy (e.g., 0.076 millimeters [0.003 inches] thick beryllium copper alloy 251/2 A hard, etc.). The beryllium copper alloy may include between about 1.8% (weight) and about 2.0% (weight) beryllium, a maximum of about 0.6% (weight) of the combination of cobalt, nickel, and iron, and the balance copper, which alloy has an electrical conductivity of between about 22% and about 28% IACS (International Annealed Copper Standard). An example of a suitable alloy is available from Brush Wellman, Cleveland, Ohio, as Brush Alloy 25 (copper alloy UNS number C17200). Other suitable materials can also be used for a gasket disclosed herein, such as stainless steel, phosphor bronze, copper-clad steel, brass, monel, aluminum, steel, nickel silver, other beryllium copper alloys, among others. Furthermore, the material may optionally be pre-plated or post-plated for galvanic compatibility with the surface on which it is intended to be mounted. Alternatively, the material may be a molded or cast polymer that is loaded or coated to be electrically-conductive.

In one particular exemplary embodiment, the gasket 100 is formed from beryllium copper alloy 25¼ hard having an initial thickness of 0.076 millimeters [003 inches], and which has undergone heat treating such that the diamond-pyramid hardness number (DPH) is about 373 or more using a 500 gram load. Continuing with this example, the beryllium copper alloy may be cleaned and have a minimum thickness of about 0.0026 inches before plating. The gasket 100 may be plated or have a finish of bright tin ASTM B-545 having a thickness of 2.5 to 7.6 microns [0.0001 to 0.0003 inches].

The gasket 100 may used with a wide range of electronic devices. For example, FIG. 8 illustrates but one example of a device for which the gasket 100 may be used. As shown in FIG. 8, the gasket 100 is installed on an exemplary pluggable optical transceiver module 160. In this particular example, the optical transceiver module 160 may be configured to support 40 Gigabits per second and 100 Gigabits per second interfaces for Ethernet, telecommunications, and other applications. The optical transceiver module 160 may also be referred to as a “CFP module,” which is a fiber optic transceiver module that meets the MSA (Multi-Source Agreement) Specification.

The optical transceiver module 160 in this example is also a hot pluggable form factor designed for optical networking applications. As just noted, the optical transceiver module 160 shown in FIG. 8 is but one example of an electronic device for which the gasket 100 may be used. Aspects of the present disclosure, however, should not be limited solely to the pluggable optical transceiver module 160 shown in FIG. 8, as embodiments of gaskets disclosed herein may be used with other pluggable optical transceiver modules, other electronic devices that are pluggable or non-pluggable with or without high energy output, etc.

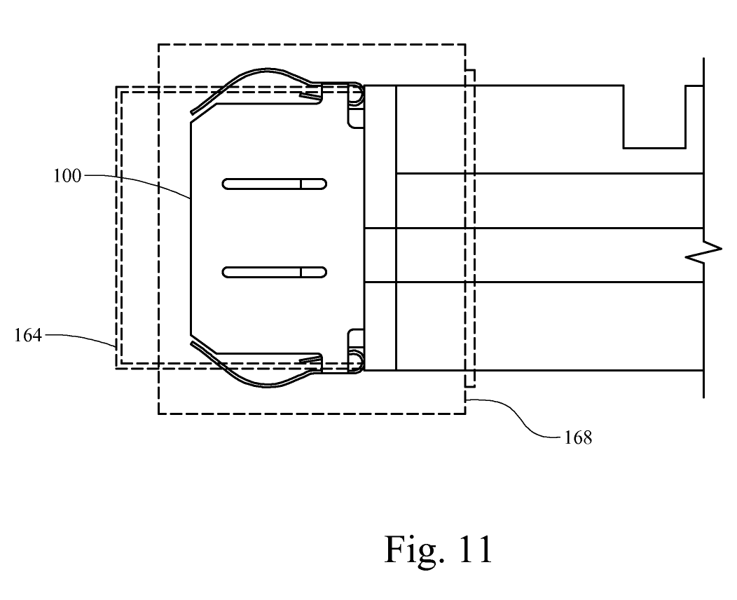

As shown in FIG. 8, the optical transceiver module 160 includes a forward portion 164 about which the gasket 100 is mounted. The optical transceiver module 160 also includes a collar 168 (FIGS. 9 and 11) and a heat sink 172.

In use, the gasket 100 may be mounted or installed circumferentially about the forward portion 164 of the optical transceiver module 160. The optical transceiver module 160 (with the gasket 100 installed thereon) may then be positioned relative to the collar 168 (FIG. 9), such that the forward portion 164 and gasket 100 are inserted or slidably received into the collar 168. For example, the collar 168 may remain stationary (e.g., the collar 168 may be attached to a sheet metal face or plate, etc.) while the optical transceiver module 160 and gasket 100 are slidably moved toward and inserted into the collar 168, e.g., with an insertion load of 36 Newtons, etc.

During the insertion of the gasket 100 into the collar 168 after the leading edges 148 of the finger elements 128 (FIG. 5) enter the collar 168, the contact portions 140 of the finger elements 128 then slide along and make electrical contact with the inside surface of the collar 168. Portions of the gasket 100 also electrically contact the forward portion 164 of the optical transceiver module 160. For example, and with reference to the finger element 128 shown in FIG. 5, the lower portion 146 and/or free end 147 (FIG. 5) of the finger element's u-shaped portion 144 and the lower surface 149 of the leading edge 148 may electrically contact the forward portion 164 of the optical transceiver module 160, e.g., with a contact load of 320 grams.

In this exemplary manner, the gasket 100 thus establishes electrical grounding contact from the forward portion 164 of the optical transceiver module 160 and the collar 168. The contact between the collar 168 and the gasket's contact portions 140 may cause the finger elements 128 to compress or flex inwardly toward the forward portion 164 of the optical transceiver module 160. This flexing or compression of the finger elements 128 may create or add to a resilient biasing force in a direction generally outward toward the collar 168, which, in turn, may help improve electrical grounding contact between the finger elements 128, the collar 168, and forward portion 164 of the optical transceiver module 160.

Accordingly, exemplary embodiments of gaskets disclosed herein may be used for providing 360 degree EMI shielding on a pluggable optical transceiver module with high energy output. Exemplary embodiments of the gaskets may contact a collar upon insertion, have a reasonable insertion load, have a significant normal load, won't snag during operation, and/or may be quickly assembled. Exemplary embodiments disclosed herein may accomplish one or more of these by using a soft, heat treatable material for gasket that also has a profile geometry that is slightly loaded during installation.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). Similarly, it is envisioned that disclosure of two or more ranges of values for a parameter (whether such ranges are nested, overlapping or distinct) subsume all possible combination of ranges for the value that might be claimed using endpoints of the disclosed ranges.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. An electromagnetic interference (EMI) shielding and/or grounding gasket comprising:
one or more sides;
slots along the one or more sides; and
finger elements defined by the slots, the finger elements including contact portions for electrically contacting at least one electrically conductive surface adjacent to a mounting surface when the gasket is mounted thereto with its one or more sides disposed about and in electrical contact with the mounting surface, whereby the gasket is operable for establishing an electrically conductive pathway between the electrically-conductive surface and the mounting surface.

2. The gasket of claim 1, wherein the gasket is configured to be mounted to a mounting surface of a optical transceiver module with the gasket's one or more sides circumferentially disposed about and in electrical contact with the mounting surface.

3. The gasket of claim 1, wherein the gasket's one or more sides define an opening having a shape complementary to a shape of a mounting surface such that the gasket is mountable with the gasket's one or more sides circumferentially disposed about and in electrical contact with the mounting surface.

4. The gasket of claim 1, wherein the gasket is mounted to a mounting surface of a optical transceiver module with the gasket's one or more sides circumferentially disposed about and in electrical contact with the mounting surface.

5. The gasket of claim 4, wherein:
the gasket includes four sides cooperatively defining a rectangular opening;
the mounting surface of the optical transceiver module is a rectangular mounting surface of a pluggable optical transceiver module;
the gasket is mounted to the rectangular mounting surface of the pluggable optical transceiver module with each of the gasket's four sides disposed along and in electrical contact with a corresponding one of the sides of the rectangular mounting surface; and
the contact portions of the gasket's finger elements are in electrical contact with an interior surface of a collar slidably disposed over the gasket, whereby the gasket is operable for providing EMI shielding and/or electrical grounding contact between the pluggable optical transceiver module and the collar.

6. The gasket of claim 1, wherein the gasket includes at least two sides with a corner slot therebetween having an open end portion and a closed end portion, whereby the corner slot allows at least some relative movement between the two sides.

7. The gasket of claim 1, wherein the gasket includes four sides cooperatively defining a rectangular opening such that the gasket is mountable about a rectangular mounting surface with the gasket's four sides circumferentially disposed about and in electrical contact with a corresponding one of the four sides of the rectangular mounting surface.

8. The gasket of claim 1, wherein each finger element curves downwardly from the contact portion to define a u-shaped hook portion at one end thereof and a leading edge at the other end thereof, the leading edge configured to be below the mounting surface when the finger element is in a free, uncompressed state, and when the finger element is in a compressed state a downward load is applied onto the mounting surface that inhibits lifting of the finger element.

9. The gasket of claim 1, wherein the finger elements are configured to be compressed or flexed inwardly toward the mounting surface when the electrically conductive surface bears against the contact portions of the finger elements and applies sufficient pressure against a force resiliently biasing the contact portions in a generally outward direction from the mounting surface.

10. The gasket of claim 9, wherein the finger elements are formed of a resilient material such that the finger elements are able to return to their unloaded positions when pressure applied against the contact portions is removed, without plastic deformation of the resilient material.

11. The gasket of claim 1, wherein:
the gasket is configured to be clipped onto a mounting surface;
the slots have both end portions closed; and/or
each finger element has a profile configured to inhibit snagging when a surface is slidably moved into and out of contact with the contact portion of the finger element.
the gasket is made of a soft, heat treatable, flexible, and/or electrically-conductive material; and/or
the gasket is configured to have an insertion load of at least 36 Newtons; and/or
the gasket is configured to have a contact load of at least 320 grams.

12. An electronic device including the gasket of claim 1.

13. A method relating to an electromagnetic interference (EMI) shielding and/or grounding gasket having one or more sides, slots along the one or more sides, and finger elements defined by the slots such that the finger elements include contact portions, the method comprising positioning the gasket relative to the mounting surface such that the gasket's one or more sides are circumferentially disposed about and in electrical contact with the mounting surface.

14. The method of claim 13, further comprising positioning an electrically conductive surface relative to the gasket to electrically contact the contact portions of the finger element, such that gasket establishes an electrically conductive pathway between the electrically-conductive surface and the mounting surface.

15. The method of claim 14, wherein:
the mounting surface comprises a portion of an optical transceiver, such that the method includes positioning the gasket circumferentially about the portion of the optical transceiver module such that the gasket's one or more sides are circumferentially disposed about and in electrical contact with the corresponding sides of the portion of the optical transceiver module; and
the electrically-conductive surface comprises an inside surface of a collar, such that the method includes electrically contacting the contact portions of the finger elements with the inside surface of the collar to thereby establish electrical grounding contact between the collar and the portion of the optical transceiver module.

16. The method of claim 15, wherein electrically contacting includes slidably inserting the gasket into the collar such that the contact portions of the finger elements are caused to move inwardly in a direction generally perpendicular to the sliding direction and generally toward the portion of the optical transceiver module.

17. A flexible clip-on EMI shielding and/or grounding gasket mountable circumferentially about a rectangular mounting surface of a optical transceiver module for providing EMI shielding and/or electrical grounding contact between the optical transceiver module and another electrically conductive surface, the gasket comprising:
four sides defining a rectangular opening complementary in shape to the rectangular mounting surface;
closed-ended slots along the four sides; and
resiliently flexible finger elements defined by the slots, the finger elements including contact portions for electrically contacting an interior surface of a collar slidably installed over the gasket while installed on the mounting surface with each of the gasket's four sides circumferentially disposed about and in electrical contact with a corresponding one of the sides of the rectangular mounting surface.

18. The gasket of claim 17, wherein:
the gasket includes at least two sides with a corner slot therebetween having an open end portion and a closed end portion, whereby the corner slot allows at least some relative movement between the two sides; and/or
each finger element curves downwardly from the contact portion to define a u-shaped hook portion at one end thereof and a leading edge at the other end thereof; and/or
the finger elements are configured to be compressed or flexed inwardly toward the rectangular mounting surface when the interior surface of the collar bears against the contact portions of the finger elements.

19. The gasket of claim 17, wherein the gasket is mounted to a rectangular mounting surface of a pluggable optical transceiver module with each of the gasket's four sides disposed along and in electrical contact with a corresponding one of the sides of the rectangular mounting surface.

20. The gasket of claim 19, wherein the contact portions of the gasket's finger elements are in electrical contact with an interior surface of a collar slidably disposed over the gasket, whereby the gasket is operable for providing EMI shielding and/or electrical grounding contact between the pluggable optical transceiver module and the collar.

21. The gasket of claim 17, wherein the gasket is mounted to a CFP pluggable optical transceiver module.
